(19) United States
(12) Patent Application Publication
(10) Pub. No.: US 2022/0376473 A1
(43) Pub. Date: Nov. 24, 2022

(54) LASER APPARATUS AND CONTROL METHOD THEREFOR

(71) Applicant: FURUKAWA ELECTRIC CO., LTD., Tokyo (JP)

(72) Inventor: Kazuaki KIYOTA, Tokyo (JP)

(73) Assignee: FURUKAWA ELECTRIC CO., LTD., Tokyo (JP)

(21) Appl. No.: 17/880,073

(22) Filed: Aug. 3, 2022

Related U.S. Application Data
(63) Continuation of application No. PCT/JP2021/002497, filed on Jan. 25, 2021.

(30) Foreign Application Priority Data
Feb. 6, 2020 (JP) 2020-018717

(51) Int. Cl. H01S 5/0687; H01S 5/024; H01S 5/068; H01S 5/06

(52) U.S. Cl. CPC H01S 5/0687; H01S 5/02415; H01S 5/06804; H01S 5/0612; H01S 5/06808

(57) ABSTRACT

A laser apparatus includes: a laser unit including: a laser element unit including a phase adjusting portion configured to adjust an optical length of a laser resonator and enable frequency of laser light to be tuned; and a monitor unit configured to obtain a monitored value corresponding to the frequency of the laser light; a temperature controller configured to control temperature of the laser unit; and a control unit configured to execute: controlling the phase adjusting portion such that the monitored value is adjusted to a target monitored value corresponding to a target frequency set as the frequency of the laser light, while maintaining temperature set for the temperature controller constant; and controlling the temperature controller such that the frequency of the laser light is adjusted to the target frequency in a case where continuous fine adjustment control of the frequency of the laser light has been instructed.

This application is a continuation of International Application No. PCT/JP2021/002497, filed on Jan. 25, 2021 which claims the benefit of priority of the prior Japanese Patent Application No. 2020-018717, filed on Feb. 6, 2020, the entire contents of which are incorporated herein by reference.

### BACKGROUND

The present disclosure relates to a laser apparatus and a control method for the laser apparatuses.

Wavelength-tunable lasers, which are laser apparatuses that are capable of outputting any wavelength for wavelength division multiplexing (WDM), are used in optical communication. A wavelength-tunable method using two wavelength-dependent filters is adopted in some wavelength-tunable lasers. These wavelength-tunable lasers, in which this wavelength-tunable method is adopted, have a configuration with two filters, a gain portion, and a phase adjusting portion that are arranged between two mirrors forming a laser resonator. Some of these elements may be integrated with one another, and a configuration having a filter and a mirror that are integrally implemented by a distributed Bragg reflector (DBR) is often used, for example (Japanese Patent No. 4918203, for example). A desired wavelength is able to be achieved by: wavelengths of the two filters being set at desired oscillation wavelengths; and then the phase adjusting portion being controlled. The phase adjusting portion has a function of adjusting optical length of the laser resonator. Changing the optical length of the laser resonator changes resonator mode wavelengths. Wavelength of light and frequency of light have an inverse relation with each other. Terms, wavelength and frequency, will be used as appropriate in the following description.

In recent years, a digital coherent communication method is mainly used in a system using a wavelength-tunable laser and a narrow spectral line width is demanded for the wavelength-tunable laser therefor.

The wavelength-tunable laser is used in the form of a wavelength-tunable laser module having a wavelength locker incorporated therein. The wavelength locker is for locking the oscillation frequency at a desired frequency and a mechanism for detecting the transmittance of light passing through a wavelength filter having periodic transmittance in relation to frequency is used in the wavelength locker. In a case where the oscillation frequency is detected, from a transmittance, to be different from the desired value, feedback control is carried out for correction of that difference. In a wavelength-tunable laser having a phase adjusting portion, this feedback is usually carried out with respect to quantity of control of the phase adjusting portion.

Wavelength-tunable laser modules are controlled to output laser light of a desired oscillation frequency. This usually does not mean that the desired oscillation frequency is continuously changeable. That is, drive conditions for a wavelength-tunable laser module may be discontinuously changed between a frequency and another frequency near that frequency.

A fine tuning frequency (FTF) function is sometimes demanded as a function of a wavelength-tunable laser module. This FTF function is a function of continuously changing frequency from a desired oscillation frequency that has been determined initially. There is a demand for a control method for a wavelength-tunable laser module, the control method achieving the FTF function (for example, Japanese Patent No. 6241931). Control achieving the FTF function may hereinafter be referred to as: FTF control; continuous fine adjustment control with respect to frequency of laser light; or simply, continuous fine adjustment control.

### SUMMARY

The phase adjusting portion usually needs to be capable of changing the phase of laser light in the laser resonator in a range of 2n radians for laser light of any frequency to be output by a wavelength-tunable laser module. Resonator mode frequency corresponding to frequency of the laser light changes according to the amount of phase adjustment by the phase adjusting portion. When the amount of adjustment is 2π radians, the frequency reaches an adjacent resonator mode adjacent to that resonator mode. Therefore, in a case where the amount of adjustment exceeds 2π radians, the amount of adjustment may then be returned to 0 radians.

However, in a case where FTF control is carried out, the frequency needs to be continuously changed over a certain frequency range. In this case, a phase adjustment even larger than 2π radians may be needed. The amount of phase adjustment is usually controlled by electric power provided to the phase adjusting portion. Therefore, there has been a problem that electric power consumption for the phase adjustment portion is increased when the amount of phase adjustment is large.

According to one aspect of the present disclosure, there is provided a laser apparatus including: a laser unit including: a laser element unit including a phase adjusting portion configured to adjust an optical length of a laser resonator and enable frequency of laser light output by the laser element unit to be tuned through control by the phase adjusting portion; and a monitor unit configured to obtain a monitored value corresponding to the frequency of the laser light; a temperature controller configured to control temperature of the laser unit; and a control unit configured to execute: a first control mode of controlling the phase adjusting portion such that the monitored value is adjusted to a target monitored value corresponding to a target frequency set as the frequency of the laser light, while maintaining temperature set for the temperature controller constant; and a second control mode of controlling the temperature controller such that the frequency of the laser light is adjusted to the target frequency set as the frequency of the laser light in a case where continuous fine adjustment control of the frequency of the laser light has been instructed.

### BRIEF DESCRIPTION OF THE DRAWINGS

FIG. 1 is a diagram illustrating a configuration of a laser apparatus according to a first embodiment;

FIG. 2 is a diagram illustrating a configuration of a laser element unit;

FIG. 3 is a diagram for explanation of adjustment of frequency of laser light;

FIG. 4 is a flowchart illustrating a control method by a control unit according to the first embodiment;

FIG. 5 is a diagram for explanation of change in frequency characteristics of a discrimination curve by change in TEC temperature;

FIG. 6 is a diagram illustrating a configuration of a laser apparatus according to a second embodiment; and

FIG. 7 is a flowchart illustrating a control method by a control unit according to the second embodiment.

### DETAILED DESCRIPTION

Modes for implementing the present disclosure (hereinafter, embodiments) will be described hereinafter by reference to the drawings. The present disclosure is not limited by the embodiments described hereinafter. The same reference sign is assigned, as appropriate, to the same portions throughout the drawings. The drawings are schematic and relations among dimensions of elements and ratios among the elements, for example, may be different from the actual ones. A portion having different dimensional relations and ratios among the drawings may also be included.

### First Embodiment

Schematic Configuration of Laser Apparatus

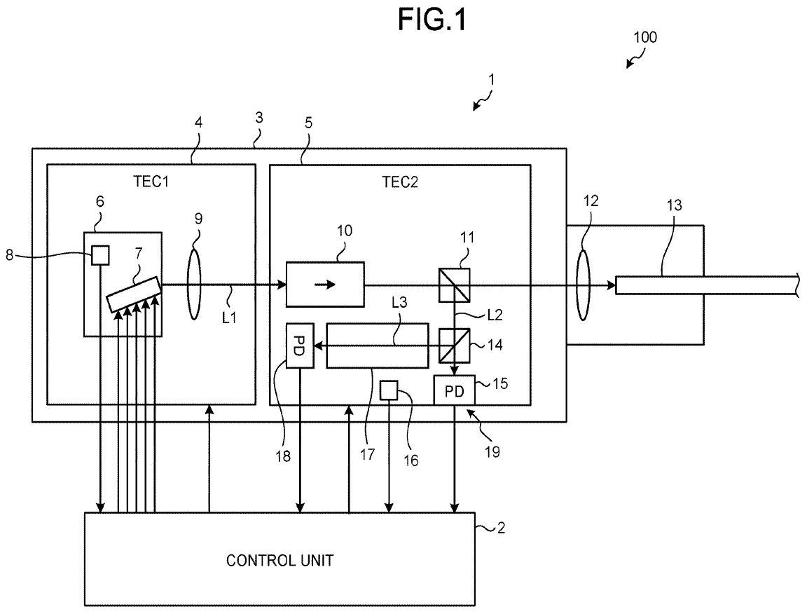

FIG. 1 is a diagram illustrating a configuration of a laser apparatus according to a first embodiment. A laser apparatus 100 includes a laser unit 1 that has been modularized and a control unit 2 that controls operation of the laser unit 1. FIG. 1 illustrates the laser unit 1 and the control unit 2 as separate units but the laser unit 1 and the control unit 2 may be integrally modularized.

Configuration of Laser Unit

The laser unit 1 includes a housing 3 and components housed or inserted in the housing 3. These components are thermo-electric cooler (TEC) elements 4 and 5, a submount 6, a laser element unit 7, a temperature sensor 8, a lens 9, an optical isolator 10, a beam splitter 11, a lens 12, an optical fiber 13, a beam splitter 14, a photodiode (PD) 15, a temperature sensor 16, an etalon filter 17, and a PD 18. The TEC elements 4 and 5 are examples of a first temperature controller and a second temperature controller, of a temperature controller. The PD 15, the etalon filter 17, and the PD 18 form a monitor unit 19.

The TEC elements 4 and 5 are mounted on a bottom plate of the housing 3. The TEC elements 4 and 5 are formed using Peltier elements, for example. The TEC elements 4 and 5 may hereinafter be respectively referred to as TEC1 and TEC2. The TEC elements 4 and 5 are controlled by being provided with electric power from the control unit 2.

The submount 6 is installed in the TEC element 4. The submount 6 is made of a material high in thermal conductivity, for example, aluminum nitride (AlN).

The laser element unit 7 is mounted on the TEC element 4, with the submount 6 interposed between the laser element unit 7 and the TEC element 4. Temperature of the laser element unit 7 is controlled by the TEC element 4. The laser element unit 7 outputs laser light L1 through drive control by the control unit 2.

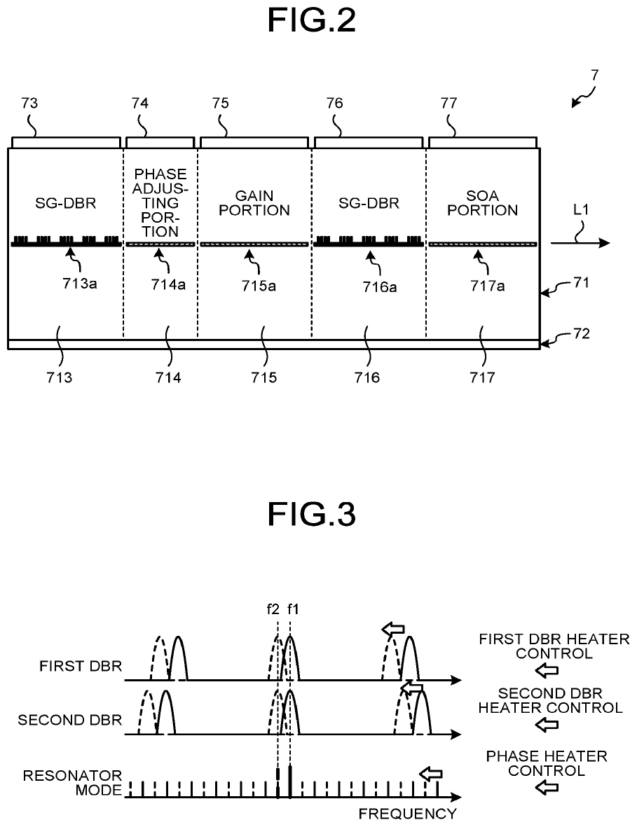

FIG. 2 is a diagram illustrating a configuration of the laser element unit 7. The laser element unit 7 includes a semiconductor portion 71, an n-side electrode 72 formed on a back surface of the semiconductor portion 71, and microheaters 73, 74, and 76 and p-side electrodes 75 and 77 that are formed on a surface of the semiconductor portion 71.

The semiconductor portion 71 is formed of an InP-based semiconductor material, for example, and has a buried waveguide structure. The semiconductor portion 71 has a configuration including the following components in the order: a first DBR portion 713 having a waveguide 713a including a sampled-grating distributed Bragg reflector (SG-DBR) configuration; a phase adjusting portion 714 having a passive waveguide 714a; a gain portion 715 having a waveguide 715a including an active layer; a second DBR portion 716 having a waveguide 716a including an SG-DBR configuration; and a semiconductor optical amplifier (SOA) portion 717 having a waveguide 717a including an active layer. The active layers each have a multiple quantum well (MQW) structure formed of, for example, a GaInAsP-based semiconductor material or an AlGaInAs-based semiconductor material. The passive waveguide 714a is formed of, for example, an i-type GaInAsP-based semiconductor material having a bandgap wavelength of 1300 nm. The waveguides having the DBR configurations are each formed of, for example, a GaInAsP-based semiconductor material or an AlGaInAs-based semiconductor material and are each configured such that portions having refractive indices different from each other are periodically arranged to form a diffraction grating.

The microheaters 73, 74, and 76 are respectively formed on surfaces of the first DBR portion 713, phase adjusting portion 714, and second DBR portion 716. The p-side electrodes 75 and 77 are respectively formed on surfaces of the gain portion 715 and SOA portion 717.

The first DBR portion 713 and the second DBR portion 716 form a laser resonator. The first DBR portion 713 and the second DBR portion 716 each have comb-like reflection peaks at periodic frequency intervals according to the inverse of the period of the diffraction grating. The first DBR portion 713 and the second DBR portion 716 have periods different from each other and are configured to enable coarse adjustment of frequency of the laser light L1 by a method called the Vernier method. The microheater 73 heating the first DBR portion 713 enables the refractive index to be changed and the comb-like reflection peaks to be shifted in the frequency axis direction. Similarly, the microheater 76 heating the second DBR portion 716 enables the refractive index to be changed and the comb-like reflection peaks to be shifted in the frequency axis direction.

The gain portion 715 is arranged between the first DBR portion 713 and the second DBR portion 716 and exerts an optical amplification effect by applying voltage between the n-side electrode 72 and the p-side electrode 75 to pass current. As a result, laser oscillation occurs.

The phase adjusting portion 714 is arranged between the first DBR portion 713 and the second DBR portion 716. The microheater 74 heating the phase adjusting portion 714 enables the refractive index to be changed and optical length of the laser resonator to be adjusted. Adjusting the optical length of the laser resonator enables frequencies of resonator modes (cavity modes) to be finely adjusted and shifted in the frequency axis direction. Finely adjusting the resonator modes enables both: selection of which resonator mode laser oscillation is to be performed in; and change of the frequency in a small range.

The SOA portion 717 is arranged on the other side of the second DBR portion 716, the other side being opposite to the side where the first DBR portion 713 and the gain portion 715 are arranged, and exerts an optical amplification effect by applying voltage between the n-side electrode 72 and the p-side electrode 77 to pass current. The SOA portion 717 optically amplifies laser light output from the second DBR portion 716 by laser oscillation and outputs the optically amplified laser light that has been increased in power, as the laser light L1, to the outside.

A bending waveguide for reducing reflection by the end face may be provided at the end of the SOA portion 717, the end being where the laser light L1 is output. A bending waveguide for reducing reflection by the end face may be provided also at an opposite end of the first DBR portion 713, the opposite end being opposite to an end where the phase adjusting portion 714 is arranged.

Description will be continued by reference to FIG. 1 again. The temperature sensor 8 is formed using, for example, a thermistor, and detects temperature of the laser element unit 7. The temperature sensor 8 outputs an electric signal including information on the detected temperature, to the control unit 2.

The lens 9 forms the laser light L1 output by the laser element unit 7 into collimated light. The optical isolator 10 is installed in the TEC element 5 and blocks light coming from the left in FIG. 1 while letting the laser light L1 pass through the optical isolator 10 to the right in FIG. 1.

The beam splitter 11 lets the laser light L1 pass through the beam splitter 11 to the lens 12 and reflects, as laser light L2, part of the laser light L1 toward the beam splitter 14. The lens 12 condenses and couples the laser light L1 to the optical fiber 13. The optical fiber 13 transmits the laser light L1.

The beam splitter 14 lets the laser light L2 pass through the beam splitter 14 to the PD 15 and reflects part of the laser light L2, as laser light L3, toward the etalon filter 17. The PD 15 receives the laser light L2 and outputs an electric signal according to intensity of the received light, to the control unit 2.

The etalon filter 17 has transmission characteristics that periodically change in relation to frequency of light. The etalon filter 17 transmits the laser light L3 at a transmittance according to frequency of the laser light L3. The PD 18 receives the laser light L3 transmitted through the etalon filter 17 and outputs an electric signal according to intensity of the received light, to the control unit 2. This electric signal includes information on frequency of the laser light L1.

The electric signals respectively output from the PD 15 and the PD 18 are used in wavelength lock control by the control unit 2 (control to adjust wavelength of the laser light L1 output from the laser element unit 7 to a target wavelength). A ratio (a monitored PD current ratio) of a current value of the electric signal output by the PD 18 to a current value of the electric signal output by the PD 15 corresponds to a monitored value corresponding to frequency of the laser light L1, as will be described more specifically later. That is, the monitor unit 19 functions to obtain a monitored value corresponding to frequency of the laser light L1.

The temperature sensor 16 is formed using, for example, a thermistor, and detects temperature of the etalon filter 17. The temperature sensor 16 outputs an electric signal including information on the detected temperature, to the control unit 2.

Schematic Configuration of Control Unit

The control unit 2 is connected to, for example, a superordinate control device (not illustrated in the drawings) including a user interface and controls operation of the laser unit 1 according to an instruction from a user via the superordinate control device.

A configuration to execute wavelength lock control and FTF control will hereinafter be illustrated and described mainly as a configuration of the control unit 2, for convenience of explanation.

The control unit 2 includes an analog-digital converter (ADC), an arithmetic unit, a storage unit, and a current source.

The ADC converts analog electric signals input from the temperature sensors 8 and 16, the PD 15, and the PD 18, into digital signals and outputs the digital signals to the arithmetic unit.

The arithmetic unit performs various types of arithmetic processing for control executed by the control unit 2 and includes, for example, a central processing unit (CPU) or a field programmable gate array (FPGA). The storage unit includes: a part formed of, for example, a read only memory (ROM) where various programs and data used by the arithmetic unit for the arithmetic processing are stored; and a part formed of, for example, a random access memory (RAM) used by the arithmetic unit: as a working space for the arithmetic processing by the arithmetic unit; or for storage of results of the arithmetic processing by the arithmetic unit. The controlling function of the control unit 2 is implemented as software by functions of the arithmetic unit and storage unit.

On the basis of instructions from the arithmetic unit, the current source supplies electric power for output of the laser light L1 and for frequency control, to the laser unit 1. In this embodiment, the arithmetic unit specifies a current value as a control quantity, to the current source. The current source supplies electric power corresponding to the specified current value, to the laser unit 1.

Adjustment of Frequency

Utilization of the Vernier effect enables frequency of the laser light L1 to be changed at the laser element unit 7. FIG. 3 is a diagram for explanation of adjustment of frequency of laser light. The top is a reflection spectrum of the first DBR portion 713, the middle is a reflection spectrum of the second DBR portion 716, and the bottom is a resonator mode spectrum. The resonator mode interval is, for example, about 20 GHz. Because this resonator mode interval is preferably small for narrowing of the spectral line width of the laser light L1, designs in which the resonator mode intervals are about 20 GHz are sometimes adopted for wavelength-tunable lasers in recent years.

Controlling the microheater 73 (which may hereinafter be referred to as the first DBR heater) by adjusting the electric power supplied shifts the reflection spectrum on the frequency axis from the form indicated by the solid line to the form indicated by the broken line, as indicated by the thick arrow. Similarly, controlling the microheater 76 (which may hereinafter be referred to as the second DBR heater) shifts the reflection spectrum on the frequency axis from the form indicated by the solid line to the form indicated by the broken line. Similarly, controlling the microheater 74 (which may hereinafter be referred to as the phase heater) shifts the spectrum on the frequency axis from the form indicated by the solid line to the form indicated by the broken line.

In the state indicated by the solid lines, laser oscillation is occurring at a frequency f1 at which a reflection peak of the first DBR portion 713 and a reflection peak of the second DBR portion 716 match each other. To achieve this state, based on the electric power supplied, the first DBR heater and the second DBR heater respectively determine frequency positions at which the reflection spectra of the first DBR portion 713 and the second DBR portion 716 come to peaks. The phase heater determines frequency positions at which the resonator modes peak, based on the electric power supplied. When the state indicated by the broken lines is reached by control of the heaters, the frequency at which a reflection peak of the first DBR portion 713, a resonator mode, and a reflection peak of the second DBR portion 716 match one another is able to be determined as a frequency f2 and frequency of the laser light L1 is thus able to be adjusted to the frequency f2. The electric power supplied to each heater may be controlled by control of the current value. That is, by supplying electric power corresponding to a current that is a control quantity, the control unit 2 controls frequency of the laser light L1. Current or electric power is an example of control quantity.

In a case where the frequency is changed by change of the refractive index through heating by the microheaters, the larger the required change in the refractive index (the frequency change), the larger the electric power consumption by the microheaters.

In a case where frequency of the laser light L1 is changed from a first frequency to a second frequency, for example, the first DBR heater and the second DBR heater are first subjected to feedforward control such that reflection peaks of the first DBR portion 713 and second DBR portion 716 overlap each other at the second frequency, and thereafter the phase heater is subjected to feedback control such that any one of the resonator modes matches the second frequency. However, the control is not necessarily performed by this method.

Start Control and Wavelength Lock Control of Laser Apparatus An example of a method of performing start control and wavelength lock control for the laser apparatus 100 will be described next. The wavelength lock control is an example of a first control mode or a first control step.

According to an instruction from the superordinate control device, for example, the control unit 2 sets a target frequency of the laser light L1 first.

Subsequently, the control unit 2 controls the TEC element 4 such that the laser element unit 7 is maintained at a constant temperature and controls the TEC element 5 such that the etalon filter 17 is maintained at a constant temperature. The temperature of the etalon filter 17 is set according to the target frequency. Specifically, by utilization of the shift of transmission characteristics of the etalon filter 17 in the frequency axis direction according to the temperature, the temperature is set such that the gradient of the transmittance of the etalon filter 17 in relation to the frequency becomes comparatively large at the target frequency. The relation between the target frequency and the temperature or the current supplied to the TEC element 5 is stored in, for example, the storage unit, as table data or a relational expression obtained by calibration beforehand. Data that are not in the table data may be calculated by interpolation using data in the table data.

Subsequently, the control unit 2 supplies current to provide input electric power corresponding to the target frequency to the microheaters 73, 74, and 76. The relation between the target frequency and the input electric power may be obtained by, for example: reference to table data or a relational expression stored in the storage unit; or calculation by interpolation.

Subsequently, the control unit 2 causes laser oscillation by supplying driving current to the gain portion 715.

The control unit 2 then drives the SOA portion 717 such that power of the laser light L1 is gradually increased, by gradually supplying driving current to the SOA portion 717. When the power of the laser light L1 reaches a predetermined value, the control unit 2 fixes the driving current.

Subsequently, wavelength lock control is performed. Specifically, the control unit 2 first converts the target frequency to a target PD current ratio corresponding to the target frequency. The relation between target frequency and target PD current ratio may be obtained by, for example, reference to table data or a relational expression stored in the storage unit, or calculation by interpolation.

Subsequently, the control unit 2 obtains a PD current ratio (a monitored PD current ratio) corresponding to the frequency of the laser light L1 at present by calculation from electric signals respectively output from the PD 15 and the PD 18.

Subsequently, the control unit 2 performs feedback control of controlling current to be supplied to the microheater 74 (phase heater) such that the monitored PD current ratio becomes equal to the target PD current ratio. A specific example of the monitored PD current ratio becoming equal to the target PD current ratio is the absolute value of the difference between the target PD current ratio and the monitored PD current ratio being in an allowable error range. This feedback control is executed by proportional-integral-derivative (PID) control or PI control. When the absolute value of the difference between the target PD current ratio and the monitored PD current ratio falls within the allowable error range, the laser element unit 7 is brought into a wavelength-locked state. For this wavelength lock, the monitored PD current ratio is used in feedback control of the phase heater.

Thereafter, the driving current to be supplied to the SOA portion 717 is increased until the intensity of received light detected by the PD 15 reaches a desired value. The laser apparatus 100 is thereby brought into a steady driven state.

At the time when the wavelength lock control is ended, the input electric power to the microheaters 73 and 76 (first and second DBR heaters) and the control temperature for the TEC element 5 are at fixed values corresponding to the target frequency of the laser light L1, and the driving current for the gain portion 715 and the control temperature for the TEC element 4 are at fixed set values regardless of the target frequency. The driving current for the SOA portion 717 is subjected to feedback control based on values detected by the PD 15, and the electric power supplied to the microheater 74 (phase heater) is subjected to feedback control based on the monitored PD current ratio.

FTF Control

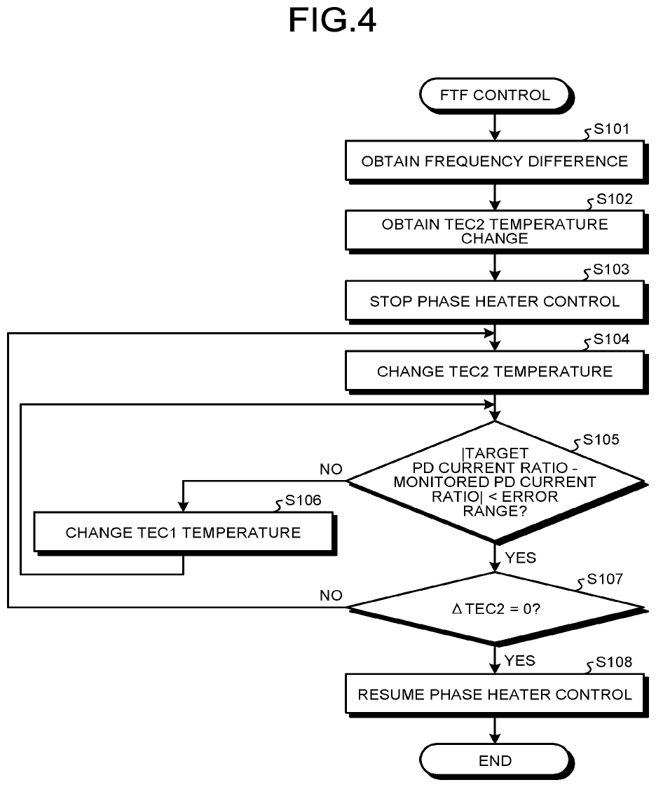

An example of a method of FTF control by the control unit 2 of the laser apparatus 100 according to the first embodiment will be described next by reference to a flowchart in FIG. 4. The FTF control is an example of a second control mode or a second control step. The flow in FIG. 4 is started when an instruction for execution of the FTF control from the frequency at present to a target frequency is received from, for example, the superordinate control device.

Firstly, at Step S101, the control unit 2 obtains a frequency difference between the target frequency of the FTF control instructed and the frequency of the laser light L1 at present.

Subsequently, at Step S102, the control unit 2 obtains a temperature difference between the control temperature for the TEC element 5 corresponding to the target frequency and the control temperature for the TEC element 5 at present, that is, an amount of temperature change required (a TEC2 temperature change) by converting the obtained frequency difference to the temperature difference.

Subsequently, at Step S103, the control unit 2 stops the feedback control of the microheater 74 (phase heater) based on the monitored PD current ratio. The electric power (current) supplied to the phase heater is thereby fixed at the value as of the time of this stoppage.

Subsequently, at Step S104, the control unit 2 changes the control temperature (TEC2 temperature) for the TEC element 5. The amount of this change is an amount resulting from division of the TEC2 temperature change into plural amounts. Changing the TEC2 temperature changes the temperature of the etalon filter 17 and shifts a discrimination curve indicating a relation between frequency and transmittance or PD current ratio in the frequency axis direction.

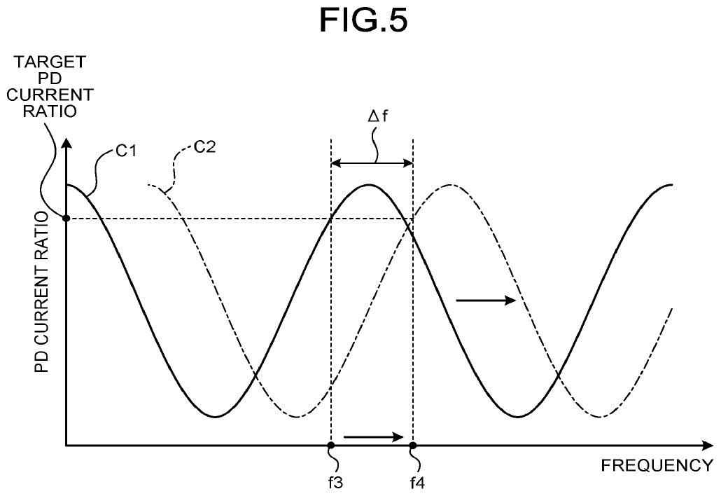

FIG. 5 is a diagram for explanation of change in frequency characteristics of a discrimination curve by change in TEC temperature. For example, the discrimination curve before the change in TEC2 temperature is represented by a curve C1. Changing the TEC temperature shifts the discrimination curve by Δf along the frequency axis as represented by a curve C2.

Subsequently, at Step S105, the control unit 2 determines, with the target PD current ratio fixed, whether the absolute value of the difference between the target PD current ratio and the monitored PD current ratio is within a predetermined error range. In a case where the absolute value is not within the predetermined error range (Step S105, No), the control temperature (TEC1 temperature) for the TEC element 4 is changed at Step S106 and the flow is returned to Step S105. In a case where the absolute value is within the predetermined error range (Step S105, Yes), the flow is advanced to Step S107.

In association with the change in TEC1 temperature, the temperature of the laser element unit 7 also changes, and the frequencies of the reflection peaks and resonator modes thus shift even if the electric current supplied to the first DBR heater, second DBR heater, and phase heater is not changed.

As illustrated in FIG. 5, before the FTF control is started, feedback control is performed such that the difference between the target PD current ratio and the monitored PD ratio is within the error range by use of the discrimination curve, the curve C1, and the frequency is locked at f3. However, when feedback control is performed, through Steps S104 to S106, such that the difference between the target PD current ratio and the monitored PD ratio is within the error range by use of the discrimination curve, the curve C2, the frequency is locked at f4. That is, in this state, the control unit 2 is performing feedback control for the TEC element 4 based on the monitored PD current ratio.

Subsequently, at Step S107, the control unit 2 determines whether or not a difference ΔTEC2 between a TEC2 temperature after the change at Step S104 and a TEC2 temperature corresponding to the target frequency is zero. In a case where ΔTEC2 is not zero (Step S107, No), the flow is returned to Step S104 and the control unit 2 changes the TEC2 temperature further. In a case where ΔTEC2 is zero (Step S107, Yes), the FTF control is ended. That is, the control unit 2 resumes the usual wavelength lock control by resuming control of the phase heater at Step S108. The flow is thereafter ended.

At the time when the flow is ended, the electric power supplied to the first DBR heater and second DBR heater is the same as that before the start of the FTF control. The driving current for the SOA portion 717 is subjected to feedback control based on values detected by the PD 15. The electric power supplied to the phase heater is subjected to feedback control based on the monitored PD current ratio. A TEC2 temperature is a temperature corresponding to the target frequency and is a temperature that is the same as that in a case where the target frequency of the FTF control is set from the beginning. A TEC1 temperature is a temperature determined by the FTF control.

The laser apparatus 100 configured as described above enables minimization of increase in power consumption for FTF control. Reasons for this minimization will be described below.

For example, in FTF control, frequency of the laser light L1 may be instructed to be changed, typically, in a range of ±8 GHz. The phase adjusting portion 714 needs to be capable of changing the phase of light by 2n radians, and if the resonator mode interval is 20 GHz, being capable of changing the phase of light by 2n radians means being capable of shifting the resonator modes by 20 GHz on the frequency axis.

In FTF control, in order to enable further change of frequency of the laser light L1 to −8 GHz from a state where the change in phase by the phase adjusting portion 714 is 0 radians, as well as further change of frequency of the laser light L1 to +8 GHz from a state where the change in phase is +2π radians, the phase needs to be able to be changed by 1.8×2π radians by the phase adjusting portion 714. In this case, as compared to a case where the change in phase by the phase adjusting portion 714 may be just 2% radians, the electric power to be supplied to the phase adjusting portion 714 is approximately doubled and electric power consumed by the phase adjusting portion 714 is thus increased.

Therefore, change of frequency of the laser light L1 in FTF control in the laser apparatus 100 is implemented by control of temperature of the laser element unit 7 by the TEC element 4. In a case where temperature of the whole laser element unit 7 is changed by the TEC element 4, just changing the temperature by 1 kelvin changes frequency of the laser light L1 by about 10 GHz. In this case, electric power supplied to the first and second DBR heaters and phase heater of the laser element unit 7 may be constant. The increase in electric power consumption for the temperature control by the TEC element 4 is negligibly small if the temperature change is just about 1 kelvin.

As described above, the laser apparatus 100 has an effect of enabling minimization of increase in electric power consumption for FTF control.

### Second Embodiment

Schematic Configuration of Laser Apparatus

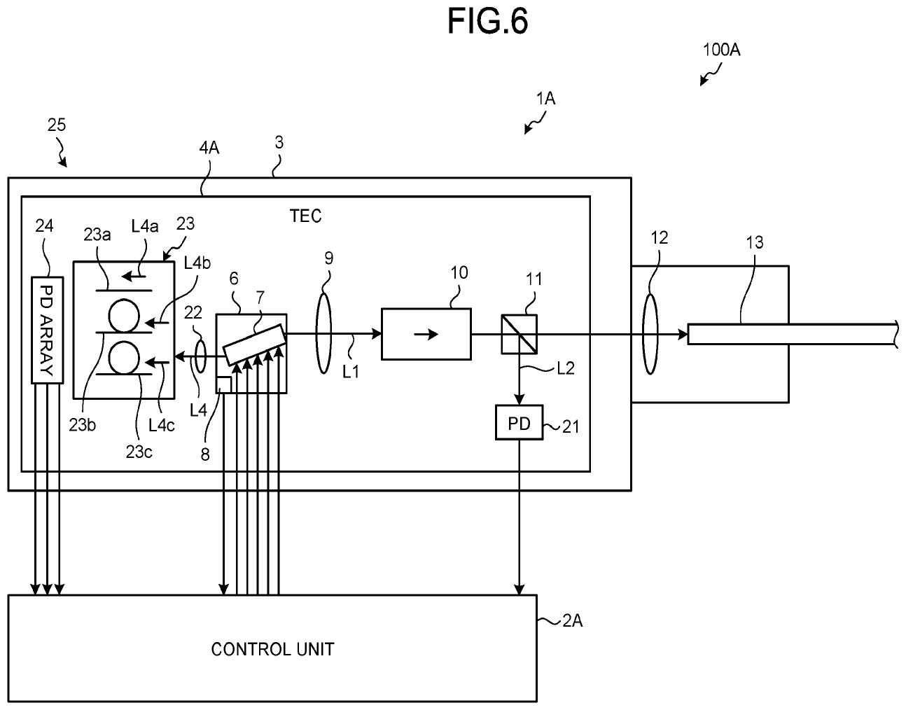

FIG. 6 is a diagram illustrating a configuration of a laser apparatus according to a second embodiment. A laser apparatus 100A includes a laser unit 1A that has been modularized and a control unit 2A that controls operation of the laser unit 1A. The laser unit 1A and the control unit 2A may be integrally modularized.

Configuration of Laser Unit

The laser unit 1A includes a configuration in which: the TEC elements 4 and 5 in the configuration of the laser unit 1 have been replaced by a TEC element 4A; the beam splitter 14, the PD 15, the PD 18, the temperature sensor 16, and the etalon filter 17 in the configuration of the laser unit 1 have been eliminated; and a PD 21, a lens 22, a planar lightwave circuit (PLC) 23, and a PD array 24 that are housed in a housing 3 have been added. The PLC 23 and the PD array 24 form a monitor unit 25. Description of components that are common to the laser unit 1A and the laser unit 1 will hereinafter be omitted, as appropriate.

The TEC element 4A is mounted on a bottom plate of the housing 3. The TEC element 4A is formed using a Peltier element, for example. A submount 6, a laser element unit 7, a temperature sensor 8, a lens 9, an optical isolator 10, a beam splitter 11, the PD 21, the lens 22, the PLC 23, and the PD array 24 are installed in the TEC element 4A. The TEC element 4A is an example of a temperature controller that collectively controls temperature of the laser element unit 7 and temperature of the monitor unit 25.

The PD 21 is installed in the TEC element 4A and similarly to the PD 15 of the laser apparatus 100, receives laser light L2 and outputs an electric signal according to intensity of the received light to the control unit 2A. The PD 21 functions to obtain a monitored value corresponding to an intensity of laser light L1.

The lens 22 is installed in the TEC element 4A, condenses laser light L4 output from a first DBR portion 713 end of the laser element unit 7 and resulting from laser oscillation by the laser element unit 7 similarly to the laser light L1, and optically couples the condensed laser light L4 to the PLC 23.

The PLC 23 includes a transmission waveguide 23a and optical filters 23b and 23c. The PLC 23 branches the laser light L4 into three, laser light L4a, laser light L4b, and laser light L4c, and causes the laser light L4a, laser light L4b, and laser light L4c to be respectively input to the transmission waveguide 23a and the optical filters 23b and 23c. The transmission waveguide 23a transmits the laser light L4a as is and outputs the transmitted laser light L4a to the PD array 24. The optical filters 23b and 23c both have transmission characteristics that periodically change at approximately the same period in relation to frequency of light but that are shifted in phase by π/2 from each other. The optical filters 23b and 23c transmit the laser light L4b and laser light L4c at transmittances according to frequencies of the laser light L4b and laser light L4c (equal to the frequency of the laser light L1) and outputs the transmitted laser light L4b and laser light L4c to the PD array 24. The optical filters 23b and 23c may each be formed using a ring resonator filter or an asymmetrical Mach-Zehnder filter.

The PD array 24 includes three PDs, receives, respectively through these PDs, the laser light L4a, laser light L4b, and laser light L4c respectively output from the transmission waveguide 23a and optical filters 23b and 23c, and respectively outputs electric signals according to intensities of the received light to the control unit 2A. These electric signals include information on the intensity or information on the frequency of the laser light L1. Each of the electric signals output from the PD array 24 is used in wavelength lock control by the control unit 2A. A ratio (a monitored PD current ratio) of a current value of the electric signal for the laser light L4a from the transmission waveguide 23a to a current value of the electric signal for the laser light L4b or L4c from the optical filter 23b or 23c corresponds to a monitored value corresponding to a frequency of the laser light L, as will be described more specifically later. That is, the monitor unit 25 functions to obtain a monitored value corresponding to a frequency of the laser light L1. Which one of the electric signals for the laser light from the optical filters 23b and 23c is to be used is selected according to a frequency of the laser light L1 to be controlled. Specifically, one of the optical filters 23b and 23c having a larger gradient of transmittance in relation to frequency at a frequency to be controlled is selected. The detection sensitivity for frequency is thereby increased because change in transmittance in relation to change in frequency is larger.

Schematic Configuration of Control Unit

Description of the control unit 2A will be omitted because the control unit 2A has a configuration similar to that of the control unit 2.

Start Control and Wavelength Lock Control of Laser Apparatus

Start control and wavelength lock control for the laser apparatus 100A may be implemented by a method similar to that for the laser apparatus 100. However, selection of which one of output from the optical filter 23b or output from the optical filter 23c is to be used is made according to a target frequency. Notably, temperature of the laser element unit 7 and temperature of the monitor unit 25 are controlled collectively by the TEC element 4A. Including the optical filters 23b and 23c in the monitor unit 25 and using one of the optical filters 23b and 23c selected eliminates the need for individual temperature control of the monitor unit 25.

At the time when the wavelength lock control is ended, input electric power to microheaters 73 and 76 (first and second DBR heaters) is at fixed values corresponding to a target frequency of the laser light L1 and driving current for a gain portion 715 and control temperature for the TEC element 4A are at fixed set values regardless of the target frequency. Driving current for an SOA portion 717 is subjected to feedback control based on values detected by the PD 21, and electric power supplied to a microheater 74 (phase heater) is subjected to feedback control based on a monitored PD current ratio.

FTF Control

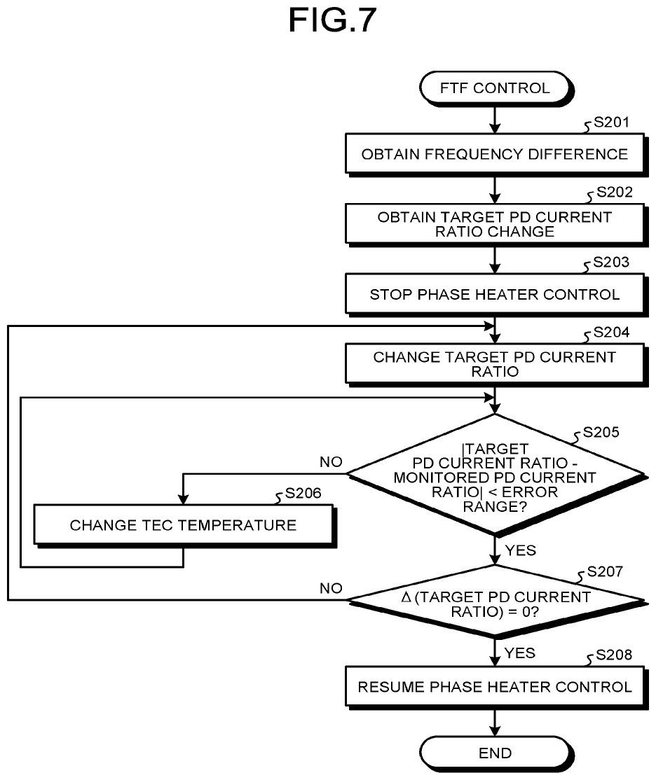

An example of a method of FTF control by the control unit 2A of the laser apparatus 100A according to the second embodiment will be described next by reference to a flowchart in FIG. 7. The FTF control is an example of a second control mode or a second control step. The flow in FIG. 7 is started when an instruction for execution of the FTF control from the frequency at present to a target frequency is received from, for example, a superordinate control device.

Firstly, at Step S201, the control unit 2A obtains a frequency difference between a target frequency of the FTF control instructed and the frequency of the laser light L1 at present.

Subsequently, at Step S202, the control unit 2A obtains a target PD current ratio change, that is, a difference between a target PD current ratio corresponding to the target frequency and a target PD current ratio corresponding to the frequency of the laser light L1 at present by converting the obtained frequency difference to the target PD current ratio change. The relation between frequency and target PD current ratio may be obtained by, for example, reference to table data or a relational expression stored in a storage unit, or calculation by interpolation.

Because the TEC element 4A in the laser apparatus 100A collectively controls temperature of the laser element unit 7 and temperature of the monitor unit 25, when the temperature of the laser element unit 7 is changed by the TEC element 4A, the temperature of the monitor unit 25 is also changed. Changing the temperature of the monitor unit 25 shifts a discrimination curve indicating a relation between frequency of the optical filter 23b or 23c and transmittance (or PD current ratio) in the frequency axis direction.

Accordingly, in this control method, a correcting step of correcting a target PD current ratio stored in a storage unit is performed in consideration of temperature dependence of each of the laser element unit 7 and the optical filters 23b and 23c. For example, a target PD current ratio stored is corrected by being multiplied by {1−(df/dT)/(dF/dT)}, where df/dT is an amount of shift f of transmission characteristics of the optical filter 23b or 23c in the frequency axis direction in relation to a change in temperature T, and dF/dT is a change in frequency F of the laser light L1 of the laser element unit 7 in relation to the change in temperature T.

In the FTF control, in a case where the optical filter used in wavelength lock control for the target frequency is different from the optical filter used in wavelength lock control for the frequency of the laser light L1 at present, the optical filters may be switched before start of the PTF control in advance or may be switched in the process of the FTF control.

Subsequently, at Step S203, the control unit 2A stops the feedback control for the microheater 74 (phase heater) based on the monitored PD current ratio. The electric power (current) supplied to the phase heater is thereby fixed to the value as of the time of this stoppage.

Subsequently, at Step S204, the control unit 2A changes the target PD current ratio from the value at present. The amount of this change is an amount resulting from division of the target PD current ratio change into plural amounts.

Subsequently, at Step S205, the control unit 2A determines whether the absolute value of the difference between the changed target PD current ratio and the monitored PD current ratio is within a predetermined error range. In a case where the absolute value is not within the predetermined error range (Step S205, No), the control temperature (TEC temperature) for the TEC element 4A is changed (Step S206) and the flow is returned to Step S205. Changing the TEC temperature changes the frequency of the laser light L1. In a case where the absolute value is within the predetermined error range (Step S205, Yes), the flow is advanced to Step S207.

When the TEC temperature is changed, temperature of the laser element unit 7 is also changed in association with that change, and frequencies of the reflection peaks and resonator modes are shifted even if current supplied to the first DCR heater, second DCR heater, and phase heater is not controlled.

In this state, the control unit 2A is performing feedback control for the TEC element 4 based on the changed target PD current ratio and the monitored PD current ratio.

Subsequently, at Step S207, the control unit 2A determines whether or not A (a target PD current ratio) that is a difference between the target PD current ratio that has been changed at Step S204 and the target PD current ratio corresponding to the target frequency is zero. In a case where A (the target PD current ratio) is not zero (Step S207, No), the flow is returned to Step S204 and the control unit 2A changes the target PD current ratio further. In a case where A (the target PD current ratio) is zero (Step S207, Yes), the FTF control is ended. That is, the control unit 2A resumes the usual wavelength lock control by resuming control for the phase heater at Step S208. The flow is thereafter ended.

At the time when the flow is ended, the electric power supplied to the first DBR heater and second DBR heater is the same as that before the start of the FTF control. The driving current for the SOA portion 717 is subjected to feedback control based on values detected by the PD 21. The electric power supplied to the phase heater is subjected to feedback control based on the monitored PD current ratio. The target PD ratio is a value corresponding to the target frequency and is the same as the value in a case where the target frequency for the FTF control is set from the beginning. The TEC temperature is a temperature determined by the FTF control.

The laser apparatus 100A configured as described above enable, similarly to the laser apparatus 100, minimization of increase in power consumption for FTF control.

The two optical filters 23b and 23c are formed of a PLC in the second embodiment, but the optical filters 23b and 23c may be formed of an etalon filter and a spatial optical system. Furthermore, the monitor unit 25 is arranged in back of the laser element unit 7 in the second embodiment, but the monitor unit 25 may be placed at an output end of the laser element unit 7, the output end being where the laser light L1 is output. In this case, the PD array 24 may be configured to monitor intensity of the laser light L1.

Temperature change by the microheaters 73, 74, and 76 is used for changing refractive indices of the first DBR portion 713, phase adjusting portion 714, and second DBR portion 716 in the above described embodiments, but a method of injecting carriers in a waveguide by current injection may be used as another method of changing the refractive indices. In the case where the method of injecting carriers is used, the phenomenon where refractive indices are decreased by the carrier plasma effect is utilized. Using this method also enables minimization of increase in power consumption for FTF control, similarly to the above described embodiments. However, using the temperature change is advantageous for narrowing the spectral line width of the laser light L1.

Frequency of the laser light L1 is coarsely adjusted by a method called the Vernier method in the above described embodiments, but any configuration having a phase adjusting portion enables minimization of increase in power consumption for FTF control, similarly to the above described embodiments, even if a method other than the Vernier method is used for that configuration, the method being, for example, a digital supermode method.

The present disclosure has an effect of enabling minimization of increase in electric power consumption for FTF control.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A laser apparatus comprising:
a laser unit including:
a laser element unit including a phase adjusting portion configured to adjust an optical length of a laser resonator and enable frequency of laser light output by the laser element unit to be tuned through control by the phase adjusting portion; and
a monitor unit configured to obtain a monitored value corresponding to the frequency of the laser light;
a temperature controller configured to control temperature of the laser unit; and
a control unit configured to execute:
a first control mode of controlling the phase adjusting portion such that the monitored value is adjusted to a target monitored value corresponding to a target frequency set as the frequency of the laser light, while maintaining temperature set for the temperature controller constant; and
a second control mode of controlling the temperature controller such that the frequency of the laser light is adjusted to the target frequency set as the frequency of the laser light in a case where continuous fine adjustment control of the frequency of the laser light has been instructed.

2. The laser apparatus according to claim 1, wherein the control unit is configured to control, in the second control mode, the temperature controller such that the monitored value is adjusted to the target monitored value corresponding to the target frequency set as the frequency of the laser light.

3. The laser apparatus according to claim 2, wherein
the temperature controller includes
a first temperature controller configured to control temperature of the laser element unit, and
a second temperature controller configured to control temperature of the monitor unit, and
the control unit is configured to control, in the second control mode, the first temperature controller such that the monitored value is adjusted to the target monitored value, while changing the temperature of the monitor unit by controlling the second temperature controller.

4. The laser apparatus according to claim 2, wherein
the temperature controller is configured to collectively control temperature of the laser element unit and temperature of the monitor unit, and
in the second control mode, the control unit is configured to correct the target monitored value based on temperature dependence of the frequency of the laser light at the laser element unit and temperature dependence of the monitored value at the monitor unit in relation to the frequency of the laser light, and while changing the target monitored value that has been corrected, control the temperature controller such that the monitored value is adjusted to the target monitored value that has been corrected.

5. A control method for a laser apparatus including a laser unit and a temperature controller configured to control temperature of the laser unit, the laser unit including a laser element unit and a monitor unit configured to obtain a monitored value corresponding to frequency of laser light output by the laser element unit, the laser element unit including a phase adjusting portion configured to adjust optical length of a laser resonator and enable the frequency of the laser light to be tuned through control by the phase adjusting portion, the laser apparatus being configured to be capable of executing a first control step of controlling the phase adjusting portion such that the monitored value is adjusted to a target monitored value corresponding to a target frequency set as the frequency of the laser light while maintaining temperature set for the temperature controller constant, the control method comprising:
a second control step of controlling the temperature controller such that the frequency of the laser light is adjusted to the target frequency set as the frequency of the laser light in a case where continuous fine adjustment control of the frequency of the laser light has been instructed.

6. The control method according to claim 5, wherein at the second control step, the temperature controller is controlled such that the monitored value is adjusted to the target monitored value corresponding to the target frequency set as the frequency of the laser light.

7. The control method according to claim 6, wherein at the second control step, temperature of the laser element unit is controlled such that the monitored value is adjusted to the target monitored value while temperature of the monitor unit is changed.

8. The control method according to claim 6, wherein
at the second control step, temperature of the laser element unit and temperature of the monitor unit are collectively controlled, and
the second control step includes:
a correcting step of correcting the target monitored value based on temperature dependence of the frequency of the laser light at the laser element unit and temperature dependence of the monitored value at the monitor unit in relation to the frequency of the laser light; and
a control step of controlling, while changing the target monitored value that has been corrected, the temperature controller such that the monitored value is adjusted to the target monitored value that has been corrected.
